(19) United States
(12) Patent Application Publication
(10) Pub. No.: US 2012/0180854 A1
(43) Pub. Date: Jul. 19, 2012

(54) MECHANICAL STACKING STRUCTURE FOR MULTI-JUNCTION PHOTOVOLTAIC DEVICES AND METHOD OF MAKING

(76) Inventors: Mathieu BELLANGER, Oxford (GB); Stephen Day, Chipping Norton (GB); Matthias Kauer, Oxford (GB)

(21) Appl. No.: 13/008,425

(22) Filed: Jan. 18, 2011

(51) Int. Cl. H01L 31/06; H01L 31/0232

(52) U.S. Cl. 136/255; 438/65; 257/E31.127

(57) ABSTRACT

A multi-junction photovoltaic structure which includes a first photovoltaic sub-cell having at least one junction, a second photovoltaic sub-cell having at least one junction and having a band gap smaller than a smallest band gap of the first photovoltaic sub-cell, and an interlayer that provides optical coupling between the first and second photovoltaic cells, wherein the interlayer has a physical thickness substantially similar or less than a vacuum wavelength of light corresponding to a smallest band gap of the second photovoltaic sub-cell.

### TECHNICAL FIELD

The invention relates to photovoltaic cells and, more particularly, to multi-junction photovoltaic cells. In addition, the invention relates to a device structure design for achieving a higher efficiency and method of making such structure.

### BACKGROUND ART

Multi-junction photovoltaic cells include at least two semiconductor junctions that provide photovoltaic action. For example, the semiconductor junctions may include Schottky junctions, p-n junctions or p-i-n junctions. The semiconductor junction(s) providing photovoltaic action will be referred to hereafter as a junction(s). Each junction operates in a different wavelength range of the incident light spectrum. The junctions are designed to operate together more efficiently than could be achieved by using only a single junction. Thus multi-junction cells are commonly referred to according to the number of junctions they include—for example, single junction, tandem junction, triple junction and four-junction cells.

Multi-junction cells are typically optically connected in series such that light not absorbed by a first junction is transmitted to a second junction and so on. Alternatively, they may be optically connected in parallel such that the wavelength range of the light spectrum is first divided into at least two portions whereby each portion is directed to the junction that can utilize it most efficiently.

Multi-junction cells enable photovoltaic cell efficiencies far above the well-known Schockley-Queisser 1 sun efficiency limit of ˜30% for a single p-n junction with 1.1 eV band gap. Indeed, the efficiency of a multi-junction photovoltaic cell increases with the number of junctions in the cell up-to a theoretical maximum of 86.8% for an infinite number of junctions. Multi-junction solar cells are commonly used in both flat plate modules and concentrator systems. An overview of design, fabrication and function of multi-junction photovoltaic cells can be found in “Advances in High-Efficiency III-V Multi-junction Solar Cells”, R. R. King et al., Adv. in Opt. Elect, Vol. 2007, and “III-V multi-junction solar cells for concentrating photovoltaics”, H. Cotal et al., Energy Environ. Sci., Vol. 2, p. 174-192, 2008.

Multi-junction photovoltaic cells can be divided into two main categories, known as a) monolithic multi-junction cells; and b) mechanically stacked multi-junction cells. Monolithic multi-junction photovoltaic cells consist of all the junctions of the photovoltaic cell formed in series on the same substrate. However, a number of practical constraints mean that it is challenging to form monolithic multi-junction cells. These include:
The photocurrent generated by each junction should preferably be substantially similar—so called “current matched”—in order that no junction is limited by any other junction in series by obeying Kirchhoff's first rule. This requires appropriate combination of materials with suitable band gap and thickness;
Each junction must be connected by a tunnel-junction to prevent the formation of an opposing photo-voltage at the interface between the junctions, which would reduce the open circuit voltage. The tunnel junction should be of sufficiently low resistance so as not to adversely affect the fill factor of the cell. These criteria require the formation of an abrupt junction between high-quality, heavily doped n- and p-type materials. Under high concentration the tunnel junction must also be able to sustain high current densities.
The lattice constant of each layer in the stack must be substantially similar—so called “lattice matched” —in order to promote the formation of high quality material with a low defect density.

The above constraints mean that the practical efficiency of monolithic cells with four junctions (33.6% under one sun AM0 in “Concentrator Solar Cell Production Capability, Reliability Assessment, and Laboratory Results at Emcore” D. Aiken et al. Proc. CPV6, 2010) is frequently less than the one of state-of-the-art three-junction monolithic cells currently 35.8% under one sun AM1.5G (Takamoto et al., III-V compound solar cells, SHARP Technical Journal, Vol. 100 p. 1-21, February 2010).

Furthermore, current matched solar cells are sensitive to diurnal variations in the solar spectrum, which change the current generated by each junction resulting in current-mismatching and a reduction in the overall efficiency of the cell compared with standard test conditions.

One means of alleviating the lattice-matching constraint is to use a step-graded buffer layer that can gradually accommodate the strain between the substrate and the upper lattice-mismatched material. However, growing a four- (or more) junction monolithic cell with optimized band-gaps requires several buffer layers, which tends to increase the dislocation density and the recombination loss within the cell, thereby limiting the efficiency of the four- (or more) junction photovoltaic cell.

Mechanically stacked multi-junction cells include independent photovoltaic cells (with band-gaps optimized to the different portions of the solar spectrum), known hereafter as sub-cells, that are mechanically brought together without any lattice-matching constraint. Each sub-cell of the mechanical stack may comprise a single junction or multiple monolithic junctions and each mechanically stacked cell may include more than two sub-cells. Mechanical stacking of sub-cells allows the combination of a wide range of material system such as (GaInP/GaAs)/Si (“Three-junction solar cells comprised of a thin film GaInP/GaAs tandem cell mechanically stacked on a Si cell”, Y. Yazawa et al., Proc. IEEE 26^{th} PVSC, Sep. 30, 1997), (InGaP/GaAs)/InGaAs (“InGaP/GaAs and In GaAs mechanically stacked triple junction solar cells”, T. Takamoto et al., Proc. IEEE 26^{th} PVSC, Sep. 30, 1997), GaAs/GaInAsP (“Mechanically stacked GaAs/GaInAsP dual-junction solar cell with high conversion efficiency of more than 31%”, T. Yamada et al., JJAP, Vol. 44, p. 988-990, Jul. 22, 2005) or GaAs/GaSb (U.S. Pat. No. 4,746,371, P. S McLeod et al., published May 24, 1988). Each of the mechanically stacked sub-cells can be independently connected in either a current-matched or voltage-matched configuration. For example, voltage-matched configuration offers an inherent robustness regarding spectral variation compared to monolithic multi-junction cells. U.S. Pat. No. 6,353,175 B1 (L. Fraas, published Mar. 5, 2002) describes one such voltage-matched configuration.

Two main technical problems exist for mechanically stacked cells.

The first technical problem relates to the optical coupling losses which result in reduced transmission of light from the upper to the lower mechanically stacked sub-cells. Optical losses result in a direct decrease of the current density in the lower sub-cell(s). There can be different contributions to these optical losses: A first contribution is free carrier absorption of sub-band gap photons in the upper sub-cell(s). This loss may only be significant if the upper sub-cells are supported on a doped substrate. A second significant contribution is the absorption, scattering and reflection losses in the adhesive layer commonly used between the mechanically stacked cells. The adhesive layer is typically at least tens of microns thick in the conventional mechanically stacked cell design.

The second technical problem relates to the thermal management of the mechanical stack due to heat transfer between the upper and lower sub-cells. In a concentrator system, around 60% of the light is not converted into electricity but instead converted to heat within the multi-junction cell. This increases the overall temperature of the cell and thereby decreasing the efficiency of the concentrator system. It is thus desirable to find an efficient way to dissipate the heat within the mechanically stacked cell.

Several methods have been used to tackle these optical and thermal challenges:

L. D. Partain et al. (“26.1% solar cell efficiency for Ge mechanically stacked under GaAs” J. Appl. Phys., 62, Oct. 1, 1987) describe a method of minimizing free carrier absorption in the substrate by using a substrate with a low dopant concentration for the upper sub-cell.

U.S. Pat. No. 5,458,694 (L. T. Nuyen, published Oct. 17, 1995) discloses an alternative means of eliminating free carrier absorption by removing completely the substrate in a process known as Epitaxial Lift-Off whereby a soluble layer is formed between the active portion of the cell and the substrate. It is possible to selectively dissolve the material of the soluble layer enabling the substrate to be removed from the cell and optionally re-used for growth of a new cell.

Alternatively the substrate may be removed by wet or dry etching. In this case an etch stop layer is formed between the cell and the substrate and the substrate of the cell can not be reused. (“Towards highly efficient 4-terminal mechanical photovoltaic stacks”, G. Flamand et al., III-Vs Review, Vol. 19, Issue 7, p. 24-27, September 2006).

Reflection losses over the spectral response range of the lower sub-cell(s) can be reduced by employing antireflection coatings on the opposing surfaces at the interface between the two mechanically stacked sub-cells, as described in the publication “31% efficient GaAs/Silicon mechanically stacked multi-junction concentrator solar cell”, J. M Gee et al., Proc. IEEE 20th PVSC, 1988. However, due to the large refractive index difference between the sub-cells (n˜3-4) and the adhesive (n˜1.4-1.5), these reflection losses can still be theoretically up to ˜8% and ˜5% even when multilayer anti-reflection coatings are used respectively.

The absorption and scattering losses in the adhesive layer are more difficult to assess as they depend on the adhesive material/thickness. Even though these losses should theoretically account for less than <5% when using 20 um thick Silicone based-adhesive, practical External Quantum Efficiency measurements on mechanically stacked multi-junction solar cells (“6 terminal mechanically stacked multi-junction solar cells”, L. Zhao et al., Proc. 25^{th} EUPVSEC, 2010) suggest that the actual absorption and scattering losses within the adhesive layer are significantly higher.

With regard to thermal management, U.S. Pat. No. 4,746,371 discloses using separate heat spreaders for the upper and lower mechanically stacked sub-cells. A disadvantage of this approach is the cost and weight associated with adding such features to the system. In addition, the upper and lower sub-cells are separated by a large air-gap that induces optical losses by reflections and absorption, as discussed previously.

To be cost effective, the efficiency of the mechanically stacked cell needs to be further optimized under real operating conditions by addressing both optical and thermal coupling challenges described above.

### ADDITIONAL RELEVANT PRIOR ART

U.S. Pat. No. 4,461,922 July 1984 Gay et al.
U.S. Pat. No. 4,658,086 April 1987 McLeod et al.
U.S. Pat. No. 5,091,018 February 1992 Fraas et al.
U.S. Pat. No. 6,459,034B2 October 2002 Muramoto et al.

### SUMMARY OF INVENTION

An object of the present invention is a mechanical stacking design and method that addresses the technical problems of achieving good optical and thermal coupling between mechanically stacked sub-cells. More specifically the present invention discloses a sub-wavelength thickness intermediate layer, an interlayer, sandwiched between the mechanically stacked upper and lower photovoltaic sub-cells. The interlayer is defined in the present invention as a substantially planar region of physical thickness X bounded by the back and front surfaces of the upper and lower sub-cells respectively.

In this context, and for the avoidance of doubt, the following definitions apply:

The orientation and order of the sub-cells in the mechanical stack is defined with reference to the incident light direction as follows: Light shall be incident on the top surface of the mechanically stacked cell such that in the absence of absorption it passes from top to bottom in series through each sub-cell. Furthermore, each of the sub-cells of the stack may comprise one or more junctions and are ordered such that the band gaps of the junctions comprising the stack increase sequentially from the bottom of the stack (i.e. the lower sub-cells) to the top of the stack (the upper sub-cells). Thus, the terms top and bottom refer to relative positions with respect to a given mechanical stack of sub-cells and the incident light.

The terms front and back refer to relative positions with respect to a given sub-cell and the incident light. For example, the front surface of a sub-cell is considered to be that which is closer to the top of the mechanical stack.

The terms upper and lower refer to relative positions of sub-cells with respect to both a given interlayer and the top and bottom of the stack. For example, the upper cell(s) is considered to be that which is closer to the top surface of the stack, and the lower sub-cell is considered to be that which is farther from the top surface to the stack.

The term sub-wavelength when referring to the physical thickness of the interlayer defines a length scale range that is substantially similar, or less than, the vacuum wavelength of light corresponding to the smallest band gap of the lower cell(s) in the stack.

The phrase substantially similar in the context of the thickness of the interlayer refers to a thickness within 50% greater than the vacuum wavelength corresponding to the smallest band gap of the lower cell(s) in the stack

According to the above definitions, the interlayer may comprise several component regions and may, for example, include the electrical contacts and anti-reflection (AR) coatings of the adjacent interfaces of either or both of the adjacent sub-cells. The interlayer excludes the semiconductor layers and/or the substrates of each sub-cell.

Besides retaining the advantages of common mechanical stacking structures, the additional advantages of the sub-wavelength mechanical stacking structure and method in accordance with the invention include the following:

The sub-wavelength feature of the interlayer enables an improvement to the optical coupling between the mechanically stacked sub-cells adjacent to the interlayer. More specifically, the optical transmittance of the interfaces between the mechanically stacked cells is improved over the spectral response range of the lower sub-cell(s) thanks to constructive optical interferences and reduced absorption and scattering within the interlayer, thereby increasing the current density generated by, and the corresponding efficiency of, the lower sub-cell(s) compared to conventional mechanically stacked cells.

The spectral response range of the lower cells refers to the spectral response of the sub-cells in the stack and is defined as the wavelength region lying substantially between the lowest band gap of the upper sub-cell(s) and the lowest band gap of the lower sub-cell(s).

The interlayer between stacked sub-cells improves the thermal coupling between upper and lower sub-cells thanks to its reduced thickness, structure, and thermal properties, thus reducing the operating temperature of the mechanically stacked cell, especially under high light concentration.

The interlayer also allows electrical connection or insulation of adjacent sub-cells from each other.

According to an aspect of the invention, a multi-junction photovoltaic structure is provided which includes a first photovoltaic sub-cell having at least one junction, a second photovoltaic sub-cell having at least one junction and having a band gap smaller than a smallest band gap of the first photovoltaic sub-cell, and an interlayer that provides optical coupling between the first and second photovoltaic cells, wherein the interlayer has a physical thickness substantially similar or less than a vacuum wavelength of light corresponding to a smallest band gap of the second photovoltaic sub-cell.

In accordance with another aspect, the first photovoltaic sub-cell includes a thin film triple junction made of GaInP, (In)GaAs and GaAs materials, and the second photovoltaic sub-cell includes a single junction made of Ge material.

According to another aspect, the interlayer further provides mechanical bonding between the first and second photovoltaic sub-cells.

According to still another aspect, the interlayer further provides thermal coupling between the first and second photovoltaic sub-cells.

In yet another aspect, the interlayer further provides electrical series connection between the first and second photovoltaic sub-cells.

According to another aspect, the interlayer further provides electrical insulation between the first and second photovoltaic sub-cells, each sub-cell being independently connected electrically.

In accordance with another aspect, the interlayer has a sub-wavelength thickness that corresponds to a lower solar weighted reflectance than the solar weighted reflectance obtained with a non sub-wavelength thick interlayer.

According to another aspect, the interlayer provides optical coupling with a solar weighted reflectance of <15% in the corresponding wavelength region between the smallest band gap of the first photovoltaic sub-cell and the smallest band gap of the second photovoltaic sub-cell.

With still another aspect, the interlayer provides optical coupling with a solar weighted reflectance of <10% in the corresponding wavelength region between the smallest band gap of the first photovoltaic sub-cell and the smallest band gap of the second photovoltaic sub-cell.

In still another aspect, the interlayer provides optical coupling with a solar weighted reflectance of <5% in the corresponding wavelength region between the smallest band gap of the first photovoltaic sub-cell and the smallest band gap of the second photovoltaic sub-cell.

In yet another aspect, the interlayer provides optical coupling with a solar weighted reflectance of <1% in the corresponding wavelength region between the smallest band gap of the first photovoltaic sub-cell and the smallest band gap of the second photovoltaic sub-cell.

According to another aspect, the average transmittance losses due to absorption by opaque regions in the interlayer is <10%.

According to still another aspect, the interlayer includes one or more anti-reflection (AR) coatings.

In accordance with another aspect, the interlayer includes air.

With still another aspect, the interlayer has thermal conductance Gₜₕ, where Gₜₕ>0.25 W.° C.⁻¹.

According to another aspect, the interlayer comprises a bonding agent that provides mechanical adhesion between the first and second photovoltaic sub-cells.

In accordance with yet another aspect, the interlayer comprises segregated regions of different component materials in an inhomogeneous layer.

According to another aspect, at least one of the different component materials has high thermal conductivity.

According to still another aspect, a third photovoltaic sub-cell is provided which includes at least one junction and having a band gap smaller than a smallest band gap of the second photovoltaic sub-cell, and another interlayer that provides optical coupling between the second and third photovoltaic cells, wherein the another interlayer has an optical thickness substantially similar or less than the vacuum wavelength corresponding to a smallest band gap of the third photovoltaic sub-cell.

In accordance with another aspect, at least one of the photovoltaic sub-cells is of a thin film type having been released from its original substrate

According to another aspect, the interlayer includes at least one of pillars or space beads.

According to still another aspect of the invention, a method of making the structure is provided. The method includes forming the first photovoltaic sub-cell, forming the second photovoltaic sub-cell, forming the interlayer on a surface of at least one of the first and second photovoltaic sub-cells, and mating opposing surfaces of the first and second photovoltaic sub-cells with the interlayer therebetween.

In accordance with another aspect, the forming of the interlayer includes coating the surface of at least one of the first and second photovoltaic sub-cells with a thin film material.

In yet another aspect, the interlayer includes an acrylic resin.

According to another aspect, the interlayer includes a spin-on-glass.

According to another aspect, forming of the interlayer includes direct bonding of the back and front contact layers of the first and second photovoltaic sub-cells.

In accordance with another aspect, the bonding is thermocompression bonding.

According to another aspect, at least one of the photovoltaic sub-cells is released from a substrate on which it is formed.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

In the annexed drawings, like references indicate like parts or features:

FIG. 1 is a schematic illustration of a concentrator photovoltaic system including a high efficiency sub-wavelength mechanically stacked multi-junction cell.

FIG. 2A is a sectional view of a sub-wavelength mechanically stacked multi-junction cell that includes a sub-wavelength thick interlayer between each sub-cell, in accordance with a first embodiment of the invention. FIG. 2B is a graph depicting the spectral transmittance of the interfaces between a sub-wavelength mechanically stacked GaAs/GaAs structure. FIG. 2C is a graph showing the Solar Weighted Reflectance (SWR) as a function of the thickness of the transparent medium (air) in the interlayer, for the same structure as in FIG. 2B.

FIGS. 3A and 3B represent a sectional view of a sub-wavelength mechanically stacked solar cell with two and three electrical output terminals respectively.

FIG. 4 is a schematic view of a multi-component interlayer that has different regions, each one ensuring a given function, in accordance with a second embodiment of the invention.

FIG. 5 is a sectional view of a sub-wavelength mechanically stacked solar cell that includes a plurality of sub-wavelength thick interlayers between each sub-cell, in accordance with a third embodiment of the invention.

FIG. 6 is a sectional view of a mechanically stacked solar cell whereby the sub-wavelength thick interlayer contains a continuous bonding agent, in accordance with a fourth embodiment of the invention.

FIGS. 7A and 7B represent a sectional view of a mechanically stacked solar cell whereby the sub-wavelength thick interlayer that contains discontinuous regions made of incompressible material, in accordance with a fifth embodiment of the invention. In one case these regions correspond to regularly spaced pillars (FIG. 7A), while in the other case they are composed of randomly distributed spacer beads (FIG. 7B).

FIGS. 8A and 8B represent a sectional view of a mechanically stacked solar cell that includes a sub-wavelength thick interlayer between each independently connected sub-cells using one-side contacted upper sub-cell and two-side contacted upper sub-cell respectively, in accordance with a sixth embodiment of the invention.

FIG. 9 is a sectional view of a mechanically stacked solar cell that includes a sub-wavelength interlayer in between each series connected sub-cell, in accordance with a seventh embodiment of the invention.

FIG. 10 is a sectional view of a mechanically stacked solar cell that includes a sub-wavelength interlayer in between an upper thin film GaInP/(In)GaAs/InGaAs triple junction and a lower Ge cell.

### DESCRIPTION OF REFERENCE NUMERALS

1 Sub-wavelength mechanically stacked cell
2 Secondary optics
3 Incident light
4 Primary optics
5 heat sink
7 Upper sub-cell
7 Interlayer
8 Lower sub-cell
9 Electrical output terminal
10 Front contact upper sub-cell
11 Upper sub-cell
12 Back contact upper sub-cell
13 Front contact lower sub-cell
14 Interlayer
15 Lower sub-cell
16 Back contact lower sub-cell
17 Extended front contact lower sub-cell
18 Region of function 1
19 Multi-component interlayer
20 Region of function 2
21 Region of function 3
22 Upper sub-cell 1
23 Interlayer 1
24 Intermediate sub-cell 2
25 Interlayer 2
26 Intermediate sub-cell 3
27 Lower sub-cell 4
28 Upper sub-cell
29 Anti-reflection coating 1
30 Continuous bonding layer
31 Interlayer
32 Lower sub-cell
33 Upper sub-cell
34 Pillars
35 Lower sub-cell
36 Upper sub-cell
37 transparent medium
38 Spacer beads
39 Adhesive
40 Lower sub-cell
41 Front contact upper sub-cell
42 Upper sub-cell
43 Passivated via-hole
44 Back contact upper sub-cell
45 Contact pad for back contact
46 Insulator layer
47 Front contact lower sub-cell
48 Lower sub-cell
49 Back contact lower sub-cell
50 Electrical output terminal
51 Front contact upper sub-cell
52 Upper sub-cell
53 Transparent medium
54 Back contact upper sub-cell
55 Intermediate contact grid for upper sub-cell
56 Insulator layer
57 Front contact lower sub-cell
58 Lower sub-cell
59 Back contact lower sub-cell
60 Front contact upper sub-cell
61 Upper sub-cell
62 Back contact upper sub-cell
63 Transparent dielectric medium
64 Front contact lower sub-cell
65 Lower sub-cell
66 Back contact lower sub-cell
67 Upper sub-cell
68 Interlayer
69 Lower sub-cell
70 Substrate

### DETAILED DESCRIPTION OF INVENTION

The optical transmittance T of the interfaces between the mechanically stacked sub-cells is related to the reflectance R and absorptance A by the following formula:

T=1−R−A,

where A includes both absorption and scattering losses.

Improvement to the short-circuit photocurrent density of the lower sub-cell(s) of the present invention compared with conventional mechanical stacking method as described in the background art is achieved by the reduction of reflection, scattering and absorption loss over the spectral response range of the lower sub-cell(s).

The lower reflection loss is directly related to the constructive optical interferences occurring within the interlayer.

The lower scattering and absorption loss is due to the reduced thickness of the interlayer given by the Beer-Lambert law:

A=1−e^{-αx}

where α is the absorption coefficient within the interlayer and X is the thickness of the interlayer.

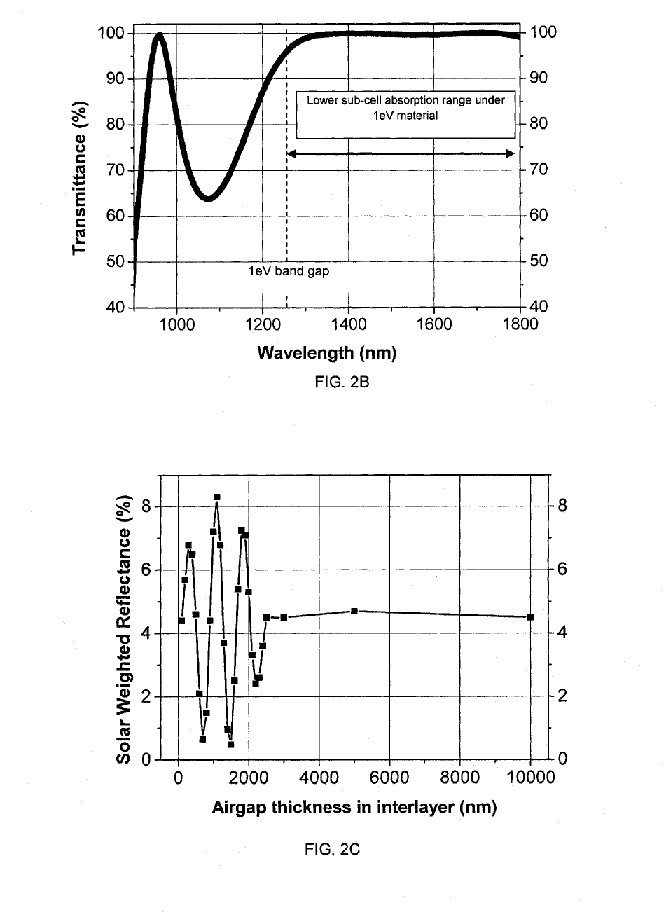

Thus technical features of the present sub-wavelength mechanical stacking invention include the following:
The total interlayer physical thickness X determines the sub-wavelength spacing between the mechanically stacked sub-cells. The optimal thicknesses of each component layer in the interlayer depend on the complex refractive index and physical thickness of the component layers, and complex refractive index of the adjacent layers. These values can be determined from optical simulations using the well known Transfer Matrix method or other suitable methods, and preferably correspond to one of the low order minima in the Solar Weighted Reflectance (SWR) of the lower sub-cell in the stack, as shown for example, in FIG. 2C.

The solar weighted reflectance of the lower sub-cell in the stack is more particularly defined as:

SWR=1−J_{sc}/J_{sc,R=0}.
J_{sc} is the short-circuit photocurrent density of the lower sub-cell in the mechanically stacked solar cell and J_{sc,R=0} is the zero reflectance short-circuit photocurrent density of the lower sub-cell in the mechanically stacked solar cell. As shown in FIG. 2C, there can be several minima in the SWR corresponding to different interlayer thicknesses.
The imaginary part (or extinction coefficient) of the complex refractive index of the interlayer should preferably be as close to zero as possible over the spectral response range of the lower sub-cells. In other words the interlayer should be substantially non-absorbing over this range.

In addition, the interlayer may perform at least one of the following functions:
The interlayer may ensure the bonding of the adjacent sub-cells and contribute therefore to the mechanical integrity of the mechanically stacked structure.
The interlayer properties may provide a means to dissipate the heat generated in the top sub-cell towards the bottom substrate and heat sink. These properties are determined by the thickness and thermal resistivity of the interlayer, which should preferably be kept as low as possible.
The interlayer may provide a means to electrically insulate or connect the sub-cells together, depending on interconnection scheme required (e.g. voltage-matching or current matching).

In order to facilitate the understanding of this invention, reference will now be made to the appended drawings of embodiments of the present invention.

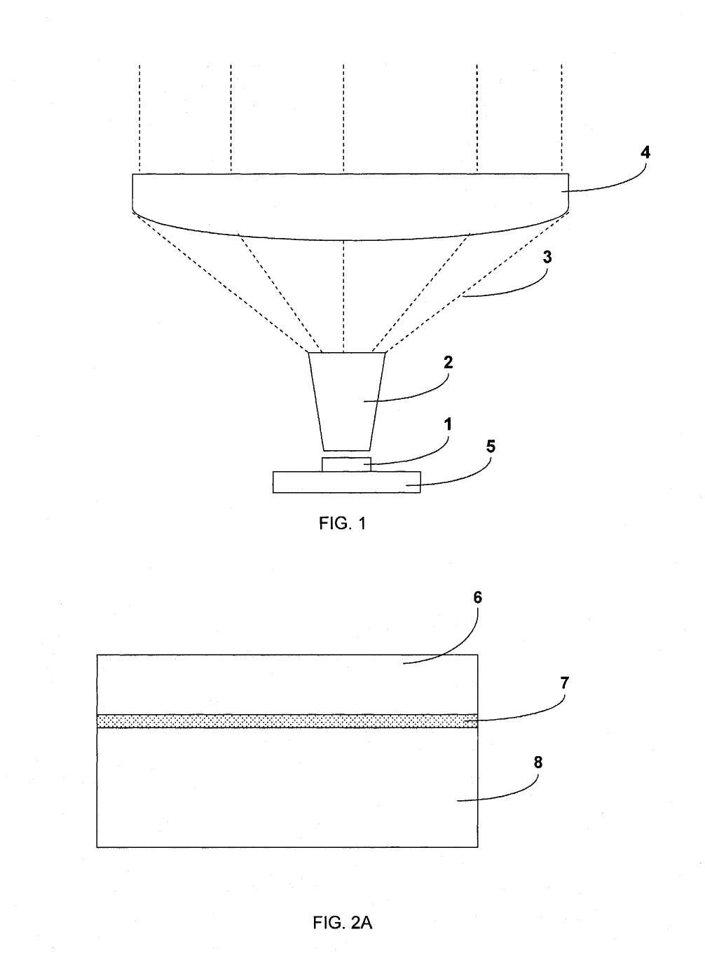

FIG. 1 describes a complete high efficiency solar concentrator system that includes a sub-wavelength mechanically stacked multi-junction cell in accordance with the present invention. The un-concentrated light 3 incident on the primary optics 4 is focused on the sub-wavelength mechanically stacked cell 1 placed on a heat sink 5 and optionally underneath a secondary optics 2. The sub-wavelength mechanically stacked multi-junction cell provides a high current density and a high efficiency according to the present invention. Optionally, the invention may be used in a flat plate-type module design without any concentrator optics.

### First Embodiment

FIG. 2A shows a constitution of a first embodiment of a sub-wavelength mechanically stacked cell that includes an interlayer 7 sandwiched between two upper and lower photovoltaic sub-cells 6 and 8. Each sub-cell is a solar cell structure that contains at least one junction and can be either supported on a substrate or stand-alone as a thin-film cell released from its original substrate, for example such as that produced by an epitaxial lift-off or substrate removal process. In the case where sub-cell 6 represents the upper or top sub-cell (first sub-cell) and sub-cell 8 represents the lower or bottom sub-cell (second sub-cell), the sub-cell 8 will have a band gap smaller than the lowest band gap of the sub-cell 6 as will be appreciated. A similar relationship applies with respect to each of the embodiments described herein.

According to the present invention, the interlayer 7 may include any of the following features:

The total thickness X of the interlayer 7 is substantially similar or less than the vacuum wavelength corresponding to a smallest band gap of the second photovoltaic sub-cell 8.

For example, in the case of Ge, InGaAs or GaSb sub-cells, X<2 μm. The thickness X of the interlayer 7 is more specifically designed in such a way that the optical coupling between stacked sub-cell(s) is improved. FIG. 2B shows the transmittance spectrum of a sub-wavelength thick interlayer 7 between two GaAs sub-cells. In this example, the interlayer 7 consists of a transparent medium (air) which is 1.5 μm thick and two single Si₃N₄AR coatings (180 nm thick with a refractive index˜2.03 at 800 nm) adjacent to the transparent medium. The transmittance losses due to absorption by opaque regions in the interlayer have not been taken into account in this example. The transmittance spectrum exhibits a region of very high transmittance (>98%) from 1250 nm to 1800 nm, corresponding to the absorption range of a ˜0.7 eV lower sub-cell 8 (ie. Ge, GaSb or InₓGa₍₁₋ₓ₎As with x˜0.52) mechanically stacked under a 1 eV upper cell 6 (ie. InₓGa₍₁₋ₓ₎As with x˜0.3 or InₓGa₍₁₋ₓ₎AsN_{y} with x ˜0.07 and y˜0.02). FIG. 2C shows the Solar Weighted Reflectance (SWR) as a function of the thickness of the transparent medium (air) in the interlayer 7, for the same structure as in FIG. 2B. The SWR curve clearly exhibits three minima, corresponding to air-gap thicknesses of 700 nm, 1500 nm and 2200 nm or interlayer thicknesses of 1060 nm, 1860 nm and 2560 nm respectively. The interlayer thickness X is preferably such that the SWR is lower than the SWR obtained with a non sub-wavelength thick interlayer, represented by the plateau in the curve of FIG. 2C. The scattering and absorption losses have been neglected in this example. If a different medium than air is used in the interlayer 7, the absorption and scattering losses in this medium will increase the SWR.

The interlayer is substantially optically transparent over the spectral response range of the lower sub-cell(s). Average transmittance losses due to absorption by one or more opaque regions within the interlayer should preferably be <10% over the spectral response range of the lower sub-cell(s). The average reflection, absorption and scattering losses in one or more substantially transparent regions within the interlayer also contribute to transmittance losses and should preferably be <10% over the spectral response range of the lower sub-cell(s).

The deleterious effect of the transmittance losses of the substantially transparent regions on the performance of the lower sub-cells in a mechanically stacked solar cell is characterized, as described previously, by the SWR. The interlayer provides optical coupling with a solar weighted reflectance of preferably <15% in the corresponding wavelength region between the smallest band gap of the upper sub-cell and the smallest band gap of the lower sub-cell(s), and more preferably <10%, yet more preferably <5%, and still further preferably <1% over the spectral response range of the lower sub-cell(s).

The interlayer in accordance with the present invention may include single or multi-layer AR coatings deposited on the opposing faces of two sub-cells prior to mechanical bonding. The role of these AR coatings is to enhance even further the optical coupling between stacked sub-cells and reduce the SWR.

The interlayer has high thermal conductance Gₜₕ, preferably higher than the one of conventionally used Silicone-based thick adhesive (Gₜₕ>0.25 W.° C.⁻¹).

The interlayer may include a bonding agent that provides the mechanical adhesion between the mechanically stacked sub-cells. For example, the interlayer may include materials to facilitate direct bonding using methods such as thermo-compression bonding, eutectic bonding, hydrophilic wafer bonding, adhesive bonding, e.g. silicone-based adhesives, cyanoacrylate-based adhesives or resins.

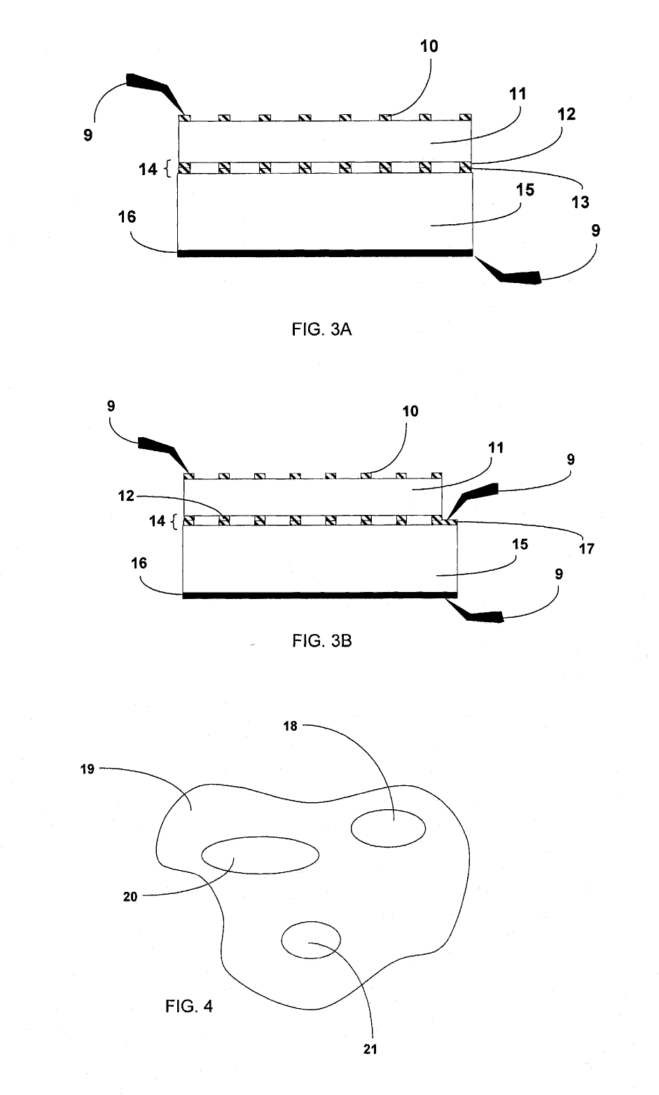

The interlayer may be electrically insulating or electrically conducting. In the former case the sub-cells are independently connected, optionally in a voltage-matched configuration. In the latter case, the sub-cells are connected in series. In both cases, there are at least two output terminals for electrical connection. FIG. 3A and FIG. 3B show an example of a sub-wavelength mechanically stacked cell with two and three output terminals 9 respectively, in the case where upper and lower sub-cells 11 and 15 are connected in series through their respective contact grids. More particularly, the upper sub-cell 11 includes front and back contacts 10 and 12, respectively, and the lower sub-cell 15 includes front and back contacts 13 and 16, respectively. The back contact 12 of the upper sub-cell 11 is connected in series to the front contact 13 of the lower sub-cell 15 via the interlayer 14. In the case of the three output terminal embodiment in FIG. 3B, an extended front contact 17 of the lower sub-cell 15 provides access for the third output terminal 9. In both cases, the thickness X of the interlayer is preferably provided by the offset produced by the joined contacts 12 and 13. Methods of joining contacts include metal eutectic bonding, thermal compression bonding, and the like.

### Second Embodiment

The interlayer may comprise more than one type of component material, each of these components providing one or more technical features of the present invention. Each component material may be spatially segregated to form an inhomogeneous interlayer with distinct regions of sub-structure as exemplified in FIG. 4. Each of the segregated regions can provide one or more of the technical features.

More specifically, in the case of a spatially segregated multi-component interlayer 19 any of the following technical features may apply:

The interlayer 19 substantially includes segregated regions (e.g., 18, 20 and/or 21) of at least one component material that is substantially optically transparent material in the spectral response range of the lower sub-cells in the mechanical stack. This transparent component can be a clear adhesive or any transparent material that is transparent over the spectral response range of the lower sub-cells(s), such as silicon dioxide, silicon nitride, aluminum oxide, hafnium oxide, ITO, and gases such as air, nitrogen, oxygen, argon, helium, carbon dioxide. Furthermore, at least the transparent component of the interlayer 19 optionally includes antireflection (AR) coatings at either interface of the transparent component. Each of the AR coatings contains at least one layer. In the case of a single layer AR coating, the optimal refractive index n_{AR1} and thicknesses e_{AR1} are respectively n_{AR1}=√n_{interlayer}·n_{sub-cell} and e_{AR1}=λ/4n_{AR1} with n_{interlayer} and n_{sub-cell} being the refractive index of the transparent component and adjacent sub-cell respectively.

The interlayer 19 may include segregated regions of at least one component material that acts as a bonding agent, e.g. a silicone-based adhesive, cyanoacrylate-based adhesive or resin.

The interlayer 19 may include segregated regions of an arbitrary or defined shape and size, such as microspheres or micropillars.

The interlayer 19 may include segregated regions of at least one component material with high thermal conductivity that provides efficient heat transfer between the sub-cells in the mechanical stack. Examples of such materials are metals, including: aluminum, copper, gold, silver etc.

The interlayer 19 may include segregated regions of at least one highly incompressible component material to control the minimum thickness of the interlayer. For example, the interlayer 19 may contain uniformly sized silica spacer beads or alternatively patterned regions of high elastic modulus material, or confined regions of incompressible fluids.

The interlayer 19 may include segregated regions of at least one conducting component material. For example, the interlayer 19 may include the back and/or front contact metallization layers of the upper and lower sub-cells respectively in order to bond the sub-cells in the mechanical stack or form electrical interconnects between, or to, the sub-cells in the mechanical stack.

Examples of typical contact materials are: metals such as gold, zinc, nickel, aluminum, silver, molybdenum, tungsten, platinum, palladium; semi-metals and semiconductors such as germanium, transparent conducting oxides such as indium tin oxide, aluminum zinc oxide

The interlayer 19 may include segregated regions of at least one electrically insulating component material. For example, dielectrics materials including: silicon dioxide, silicon monoxide, silicon nitride, aluminum oxide, polymers and resins.

The interlayer 19 may include segregated regions of at least one optically opaque material. The area of the opaque regions is ideally <10% of the total area of the interlayer.

The interlayer 19 may include segregated regions of least one liquid-phase component material including oils, water etc

The interlayer 19 may include regions of at least one gas-phase component material. For example, the interlayer 19 may be substantially porous or include voids and thus may incorporate air or any other gas such as argon, carbon dioxide, nitrogen, helium etc

The interlayer 19 may include at least one substantially evacuated region.

The interlayer 19 may include at least one material that acts to planarize the surface of at least one of the mated surfaces of the sub-cells. For example, spin-on-glass (SOG), benzocyclobutene (BCB), polyimide films, and other resins and low viscosity liquid epoxies.

A general and preferred method for making the present invention is described thereafter. The individual sub-cells are separately grown generally in a Molecular Organic Chemical Vapor Deposition (MOCVD) or Molecular Beam Epitaxy (MBE) chamber. The active area, the contacts and Anti-Reflection coatings of the sub-cells are then defined using standard photolithography, etching and deposition techniques for III-V and IV compounds materials. The multi-component interlayer between each sub-cell is then defined and patterned to provide the features of the invention already mentioned. A UV flood exposure may be required to improve the transparency of the bonding agent. One or several (pre)-curing steps can be required depending on the bonding agent present in the interlayer. These curing steps can be but not necessarily activated thermally in an oven. The sub-cells are mechanically stacked using a thermo-mechanical press to optionally apply either pressure or heat.

### Third Embodiment

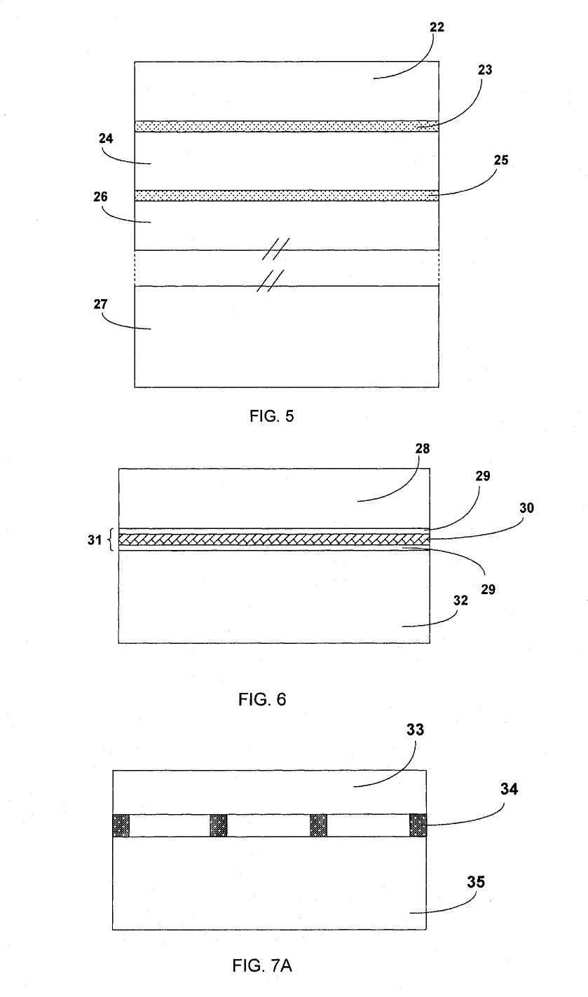

In a third embodiment, as shown in FIG. 5, the mechanically stacked cell includes at least two interlayers 23 and 25 according to the invention as described herein, and at least three sub-cells 22, 24, 26 and 27. Each sub-cell is either supported on a substrate or stand-alone as a thin-film (couple of microns thick) sub-cell. Each sub-cell has to be transparent over the spectral response range of the lower sub-cell(s).

### Fourth Embodiment

In a fourth embodiment, as shown in FIG. 6, a sub-wavelength thick interlayer 31 contains a continuous layer of bonding agent 30 in-between stacked sub-cells 28 and 32. The interlayer 31 may also comprise AR coatings and contacts. In FIG. 6, only AR coatings 29 have been shown as an example. The bonding agent 30 also acts preferably as a planarization layer in order to guarantee a good adhesion and a good spatial uniformity of the distance X between the sub-cells 28 and 32. The bonding agent 30 can be an organic or inorganic adhesive. Examples of organic adhesives are acrylic-type resin, benzocyclobutene (BCB) or Silicone-type adhesives. Examples of inorganic adhesives include Silica and metals. The bonding agent 30 is preferably spin-coated followed by solvent evaporation but also may be deposited using any deposition techniques such as Chemical Vapor Deposition, Sputter Deposition, Electron Beam, thermal evaporation and the like. The bonding agent 30 is transparent over the spectral response range of the lower sub-cells. A curing step such as UV exposure or thermal annealing may optionally be required in order to improve the bond strength and/or transparency of the bonding agent 30.

### Fifth Embodiment

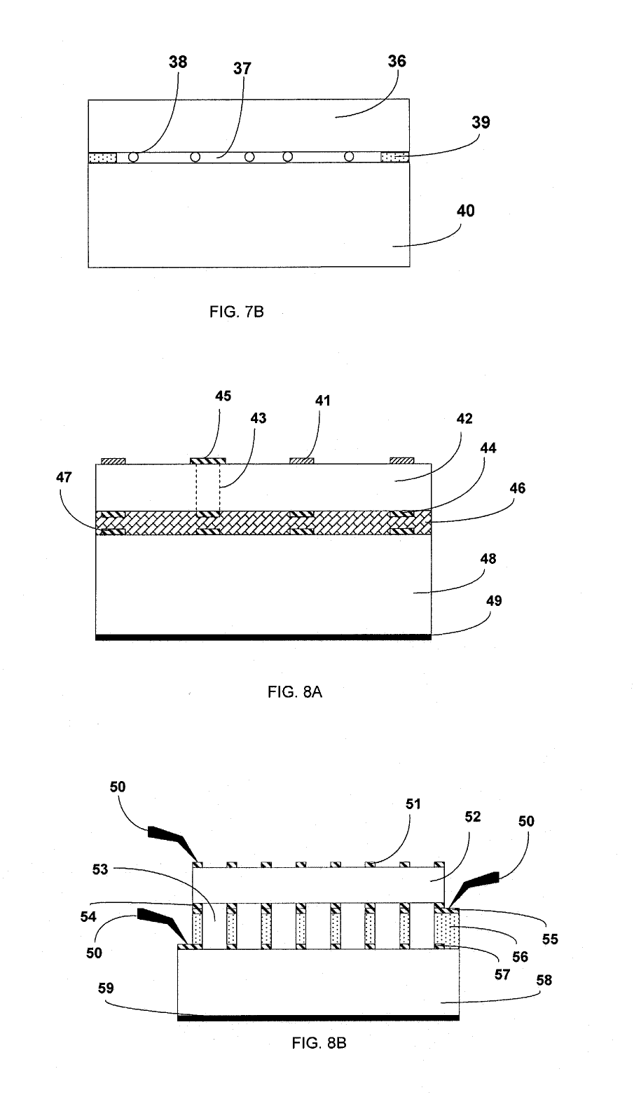

In a fifth embodiment, as shown in FIG. 7A and FIG. 7B, the sub-wavelength thick interlayer contains discontinuous regions having a thickness X whose function is to define the physical thickness X of the interlayer and to maintain the mechanical integrity of the structure. The regions must be made of highly incompressible material and therefore have a high elastic modulus. The regions can be transparent or opaque over the spectral response range of the lower sub-cell. The fraction of the area of the interlayer occupied by opaque regions should preferably be kept <10%. These regions can have any geometrical 3D shape such as rectangular or circular pillars or spheres. These regions can be regularly spaced (FIG. 7A) or randomly distributed (FIG. 7B). In the first case, the interlayer includes pillars 34 which can be patterned on the surface of one or both sub-cells 33 and 35 prior to mechanical bonding. In the latter case, for example (FIG. 7B), the interlayer includes silica or polymer spacer beads 38 which can be dispersed on the surface of one or both sub-cells 36 and 40 prior to mechanical bonding. In FIG. 7B, the adhesion between the sub-cells is performed by a low viscosity adhesive 39 applied around the active area of the sub-cells. The medium 37 in between the regions (e.g, between the pillars 34 and/or spacer beads 38) can be a solid (dielectric), gas (air, helium or the like), vacuum or liquid, and is transparent over the spectral response range of the lower sub-cell.

### Sixth Embodiment

In a sixth embodiment, as shown in FIG. 8A and FIG. 8B, the sub-wavelength thick interlayer has at least one more component materials that ensure both the mechanical bond and electrical insulation of the sub-cells. These component materials can be any dielectric or adhesive materials already discussed and have to be transparent over the spectral response range of the lower sub-cell.

In one case, an upper sub-cell 42 and lower sub-cell 48 are separated by a sub-wavelength thick interlayer as shown in FIG. 8A. The interlayer includes an electrically insulating layer 46 separating the back contact 44 of the upper sub-cell 48 and the front contact 47 of the lower sub-cell 48. The upper sub-cell 42 is one-side contacted, the back contact 44 of the upper sub-cell 42 being accessible from the top surface through a via-hole 43 process as shown in FIG. 8A. The sidewalls of the via-hole 43 are electrically insulated with a commonly used dielectric layer (Silicon nitride, Silicon dioxide or the like), and a metal pad 45 is subsequently filled into the via-hole 43 on top of the dielectric. The front contact 41 of the upper sub-cell 42 and back contact 49 of the lower sub-cell 48 provide the remaining contacts.

In another case, the upper sub-cell 52 is two-side contacted and access to the back contact 54 of the upper sub-cell 52 is realized using a thermal compression bonding method. The interlayer includes an electrically insulating layer of dielectric material 56 which is deposited on the top surface of the lower sub-cell 58. An intermediate contact grid 55 aligned with the front grid 57 of the lower sub-cell 58 is subsequently deposited and the lower and upper sub-cells are mechanically bonded using the thermal compression between the front contact grid 57 of the lower sub-cell 58 and the intermediate contact grid 55. The contact 57 and intermediate contact 55 grids can be made of a various range of metals or metal alloys with elements such as Au, Ti, In, Ge, Ni, Pt, Pd, Zn and the like. The dielectric layer 56 may be subsequently patterned to leave a gap 53 between the contact grids. This gap may be filled with a gas such as air, helium, or the like. The total thickness represented by the contact grids, intermediate metal grid and dielectric layer is equal to the thickness X of the interlayer and must be sub-wavelength thick according to the present invention.

The front contact 51 of the upper sub-cell 52 and the back contact of the lower sub-cell 58 provide the remaining electrical contacts via output terminals 50.

In both the cases of FIGS. 8A and 8B, each sub-cell can be independently electrically connected.

### Seventh Embodiment

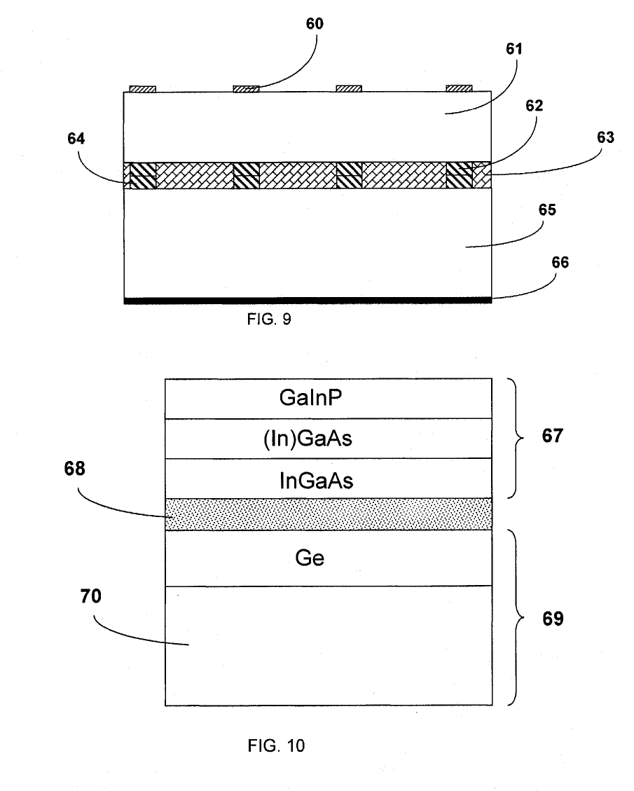

In a seventh embodiment, as shown in FIG. 9, the sub-wavelength thick interlayer has at least one more component materials that ensure both the mechanical bond and electrical connection of the sub-cells in series. These component materials can be made of a various range of metals or metal alloys with elements such as Au, Ti, In, Ge, Ni, Pt, Pd, Zn and the like. The alloy composition is selected such as to minimize the contact resistance with the semiconductor materials of the upper 61 and lower sub-cells 65. The component materials 62 and 64 can be patterned independently on each sub-cell, prior to mechanical bonding, into various geometrical shapes including those commonly used for solar cells grid contacts such as ring, fingers or inverted square designs. The gap between the component materials can be filled by at least one or more gaseous and/or solid media 63. The total thickness represented by the stacked component materials 62 and 64 is equal to the thickness X of the interlayer and must be sub-wavelength thick according to the present invention.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### Eighth Embodiment

In an eighth embodiment, as shown in FIG. 10, the upper sub-cell 67 is a thin film triple junction made of GaInP, (In)GaAs and InGaAs materials, and the lower sub-cell 69 is a single junction made of Ge material. The interlayer 68 of thickness X in between the sub-cells 67 and 69 provides the mechanical bonding, optical and thermal coupling as described in the other embodiments. The In composition in the third junction of the upper cell can be adjusted to obtain an optimal band-gap in a four-junction mechanically stacked structure close to 1 eV if the upper 67 and lower 69 sub-cells are independently connected, or close to 1.04 eV if the upper 67 and lower 69 sub-cells are connected in series. The Ge junction of the lower sub-cell 69 is either grown on a Ge substrate or on a metamorphic SiGe substrate 70. The substrate of the upper sub-cell 67 is removed after the upper 67 and lower 69 sub-cells are bonded together with an organic (silicone-based adhesive, cyanoacrylate-based adhesive, resin and the like) or inorganic adhesive (metal, silica and the like).

### INDUSTRIAL APPLICABILITY

The mechanically stacked cells according to the present invention may be used in any photo-voltaic system whereby a multi-junction solar cell is required, more specifically in both flat plate and concentrator systems, either for terrestrial or space applications.

1. A multi-junction photovoltaic structure, comprising:
a first photovoltaic sub-cell comprising at least one junction;
a second photovoltaic sub-cell comprising at least one junction and having a band gap smaller than a smallest band gap of the first photovoltaic sub-cell; and
an interlayer that provides optical coupling between the first and second photovoltaic cells, wherein the interlayer has a physical thickness substantially similar or less than a vacuum wavelength of light corresponding to a smallest band gap of the second photovoltaic sub-cell.

2. The structure according to claim 1, wherein the first photovoltaic sub-cell comprises a thin film triple junction made of GaInP, (In)GaAs and GaAs materials, and the second photovoltaic sub-cell comprises a single junction made of Ge material.

3. The structure according to claim 1, wherein the interlayer further provides mechanical bonding between the first and second photovoltaic sub-cells.

4. The structure according to claim 1, wherein the interlayer further provides thermal coupling between the first and second photovoltaic sub-cells.

5. The structure according to claim 1, wherein the interlayer further provides electrical series connection between the first and second photovoltaic sub-cells.

6. The structure according to claim 1, wherein the interlayer further provides electrical insulation between the first and second photovoltaic sub-cells, each sub-cell being independently connected electrically.

7. The structure according to claim 1, wherein the interlayer has a sub-wavelength thickness that corresponds to a lower solar weighted reflectance than the solar weighted reflectance obtained with a non sub-wavelength thick interlayer.

8. The structure according to claim 1, wherein the interlayer provides optical coupling with a solar weighted reflectance of <15% in the corresponding wavelength region between the smallest band gap of the first photovoltaic sub-cell and the smallest band gap of the second photovoltaic sub-cell.

9. The structure according to claim 1, wherein the interlayer provides optical coupling with a solar weighted reflectance of <10 in the corresponding wavelength region between the smallest band gap of the first photovoltaic sub-cell and the smallest band gap of the second photovoltaic sub-cell.

10. The structure according to claim 1, wherein the interlayer provides optical coupling with a solar weighted reflectance of <5% in the corresponding wavelength region between the smallest band gap of the first photovoltaic sub-cell and the smallest band gap of the second photovoltaic sub-cell.

11. The structure according to claim 1, wherein the interlayer provides optical coupling with a solar weighted reflectance of <1% in the corresponding wavelength region between the smallest band gap of the first photovoltaic sub-cell and the smallest band gap of the second photovoltaic sub-cell.

12. The structure according to claim 1, wherein the average transmittance losses due to absorption by opaque regions in the interlayer is <10%.

13. The structure according to claim 1, wherein the interlayer includes one or more anti-reflection (AR) coatings.

14. The structure according to claim 1, wherein the interlayer includes air.

15. The structure according to claim 1, wherein the interlayer has thermal conductance Gₜₕ, where Gₜₕ>0.25 W.° C.⁻¹.

16. The structure according to claim 1, wherein the interlayer comprises a bonding agent that provides mechanical adhesion between the first and second photovoltaic sub-cells.

17. The structure according to claim 1, wherein the interlayer comprises segregated regions of different component materials in an inhomogeneous layer.

18. The structure according to claim 17, wherein at least one of the different component materials has high thermal conductivity.

19. The structure according to claim 1, further comprising a third photovoltaic sub-cell comprising at least one junction and having a band gap smaller than a smallest band gap of the second photovoltaic sub-cell, and another interlayer that provides optical coupling between the second and third photovoltaic cells, wherein the another interlayer has an optical thickness substantially similar or less than the vacuum wavelength corresponding to a smallest band gap of the third photovoltaic sub-cell.

20. The structure according to claim 1, wherein at least one of the photovoltaic sub-cells is of a thin film type having been released from its original substrate

21. The structure according to claim 1, wherein the interlayer includes at least one of pillars or space beads.

22. A method of making a structure according to claim 1, comprising:
forming the first photovoltaic sub-cell;
forming the second photovoltaic sub-cell;
forming the interlayer on a surface of at least one of the first and second photovoltaic sub-cells; and
mating opposing surfaces of the first and second photovoltaic sub-cells with the interlayer therebetween.

23. The method according to claim 22, wherein the forming of the interlayer comprises coating the surface of at least one of the first and second photovoltaic sub-cells with a thin film material.

24. The method according to claim 23, wherein the interlayer comprises an acrylic resin.

25. The method according to claim 23, wherein the interlayer comprises a spin-on-glass.

26. The method according to claim 22, wherein forming of the interlayer comprises direct bonding of the back and front contact layers of the first and second photovoltaic sub-cells.

27. The method according to claim 26, wherein the bonding is thermocompression bonding.

28. The method according to claim 22, wherein at least one of the photovoltaic sub-cells is released from a substrate on which it is formed.
